(19) United States
(12) Patent Application Publication
(10) Pub. No.: US 2024/0387593 A1
(43) Pub. Date: Nov. 21, 2024

(54) SOLID-STATE IMAGING DEVICE

(71) Applicant: SONY SEMICONDUCTOR SOLUTIONS CORPORATION, KANAGAWA (JP)

(72) Inventors: SHOTA MORIMOTO, KANAGAWA (JP); YUSUKE OTAKE, KANAGAWA (JP); TAKUYA MARUYAMA, KANAGAWA (JP); YUJI ISOGAI, KANAGAWA (JP)

(21) Appl. No.: 18/694,435

(22) PCT Filed: Aug. 25, 2022
(86) PCT No.: PCT/JP2022/031977

§ 371 Date: Mar. 22, 2024

(30) Foreign Application Priority Data
Oct. 5, 2021 (JP) 2021-164162

(51) Int. Cl. H01L 27/146

(52) U.S. Cl. CPC H01L 27/14638

(57) ABSTRACT

To suppress blooming. A solid-state imaging device includes: a photoelectric converter that generates a charge according to an amount of received light; and a discharge path portion that is disposed between the photoelectric converter and a discharge destination of the charge and through which the charge overflowing from the photoelectric converter passes.

### TECHNICAL FIELD

Embodiments according to the present disclosure relate to a solid-state imaging device.

### BACKGROUND ART

As solid-state imaging devices, there are active pixel sensors (APSs) including an amplification element for each pixel. Among them, a complementary MOS (CMOS) image sensor that reads signal charges accumulated in a photodiode, which is a photoelectric conversion element, through a metal-oxide-semiconductor (MOS) transistor has recently been used in various applications (see Patent Document 1).

### CITATION LIST

### Patent Document

Patent Document 1: Japanese Patent Application Laid-Open No. 2013-16675
Patent Document 2: Japanese Patent Application Laid-Open No. 2020-43413

### SUMMARY OF THE INVENTION

### Problems to be Solved by the Invention

However, for example, blooming may occur due to incidence of strong light and the like. Blooming (self-pixel blooming) is, for example, a phenomenon in which signal charges are excessively generated in a photodiode, and the overflowed signal charges flow into a floating diffusion. Due to blooming, a noise component is superimposed on the signal charges, and image quality is deteriorated.

Therefore, the present disclosure provides a solid-state imaging device capable of suppressing blooming.

### Solutions to Problems

In order to solve the problem described above, according to the present disclosure, there is provided a solid-state imaging device including
a photoelectric converter configured to generate charges according to an amount of received light, and
a discharge path portion that is disposed between the photoelectric converter and a discharge destination of the charges and through which the charges overflowing from the photoelectric converter pass.

The discharge path portion may have a potential different from a potential of an outer peripheral region surrounding the photoelectric converter and the discharge path portion.

The discharge path portion may include:
a first discharge path portion disposed so as to be in contact with at least a part of the photoelectric converter, and having a potential lower than the potential of the outer peripheral region and higher than a lowest value of the potential of the photoelectric converter; and
a second discharge path portion disposed so as to allow the charges having passed through the first discharge path portion to pass therethrough, and having a potential lower than the potential of the first discharge path portion.

The discharge path portion may further include a third discharge path portion disposed between the first discharge path portion and the second discharge path portion and having a potential between the potential of the first discharge path portion and the potential of the second discharge path portion.

The discharge path portion may have a potential that gradually decreases from the photoelectric converter to the discharge destination.

The discharge path portion may have an impurity concentration different from an impurity concentration in an outer peripheral region surrounding the photoelectric converter and the discharge path portion.

A discharge transistor that resets the charges of the photoelectric converter may not be provided between the photoelectric converter and the discharge destination.

A transfer unit configured to transfer the charges generated by the photoelectric converter may be further provided, and
the discharge path portion may be disposed so as to be close to the transfer unit.

A transfer unit configured to transfer the charges generated by the photoelectric converter may be further provided,
the transfer unit is disposed so as to be in contact with a first straight portion of an outer edge of the photoelectric converter when viewed from a normal direction of a substrate surface of a substrate on which the photoelectric converter is provided, and
the discharge path portion may be disposed so as to be in contact with the first straight portion when viewed from the normal direction.

A transfer unit configured to transfer the charges generated by the photoelectric converter,
a charge accumulation unit that accumulates the charges transferred by the transfer unit, and
a reset unit configured to reset the charges accumulated in the charge accumulation unit may be further provided, and
the transfer unit and the reset unit may be disposed so as to be close to each other.

A transfer unit configured to transfer the charges generated by the photoelectric converter,
a charge accumulation unit that accumulates the charges transferred by the transfer unit, and
a reset unit configured to reset the charges accumulated in the charge accumulation unit may be further provided, and
the transfer unit and the reset unit may be disposed along a second straight portion of an outer edge of a pixel region.

The photoelectric converter may be disposed inside the substrate, and
at least a part of the discharge path portion may be disposed so as to extend in a normal direction of the substrate surface of the substrate.

The discharge path portion may be disposed so as to overlap the photoelectric converter when viewed from the normal direction.

A part of the discharge path portion may be disposed so as to extend from at least a part of the photoelectric converter in a direction along the substrate surface of the substrate, and
the other portion of the discharge path portion may be disposed so as to extend in the normal direction from a part of the discharge path portion.

The discharge destination may be shared by a plurality of pixels.

The discharge destination may be disposed so as to be close to the photoelectric converter.

The discharge destination may be a reference voltage node.

### BRIEF DESCRIPTION OF DRAWINGS

FIG. 1 is a block diagram depicting a configuration example of a solid-state imaging device according to a first embodiment.

FIG. 2 is a circuit diagram depicting a circuit configuration of one sensor pixel in the solid-state imaging device according to the first embodiment.

FIG. 3 is a plan view schematically depicting a planar configuration of one sensor pixel in the solid-state imaging device according to the first embodiment.

FIG. 4 is a cross-sectional view schematically depicting a cross-sectional configuration of the sensor pixel according to the first embodiment.

FIG. 5 is a schematic diagram depicting an example of a potential of the sensor pixel according to the first embodiment.

FIG. 6 is a plan view schematically depicting a planar configuration of one sensor pixel in a solid-state imaging device according to a comparative example.

FIG. 7 is a plan view schematically depicting a planar configuration of one sensor pixel in a solid-state imaging device according to a second embodiment.

FIG. 8 is a plan view schematically depicting a planar configuration of one sensor pixel in a solid-state imaging device according to a third embodiment.

FIG. 9 is a schematic diagram depicting an example of a potential of a PD according to the third embodiment.

FIG. 10 is a schematic diagram depicting an example of a potential of a PD according to the third embodiment.

FIG. 11 is a plan view schematically depicting a planar configuration of one sensor pixel in a solid-state imaging device according to a fourth embodiment.

FIG. 12 is a plan view schematically depicting a planar configuration of one sensor pixel in a solid-state imaging device according to a fifth embodiment.

FIG. 13 is a plan view schematically depicting a planar configuration of one sensor pixel in a solid-state imaging device according to a sixth embodiment.

FIG. 14 is a plan view schematically depicting a planar configuration of one sensor pixel in a solid-state imaging device according to a seventh embodiment.

FIG. 15A is a plan view schematically depicting a planar configuration of four sensor pixels in a solid-state imaging device according to an eighth embodiment.

FIG. 15B is a plan view schematically depicting a planar configuration of four sensor pixels in a solid-state imaging device according to a modification of the eighth embodiment.

FIG. 16 is a plan view schematically depicting a planar configuration of two sensor pixels in a solid-state imaging device according to a ninth embodiment.

FIG. 17 is a plan view schematically depicting a planar configuration of one sensor pixel in a solid-state imaging device according to a tenth embodiment.

FIG. 18 is a cross-sectional view schematically depicting a cross-sectional configuration of a sensor pixel according to the tenth embodiment.

FIG. 19 is a plan view schematically depicting a planar configuration of one sensor pixel in a solid-state imaging device according to an eleventh embodiment.

FIG. 20 is a cross-sectional view schematically depicting a cross-sectional configuration of the sensor pixel according to the eleventh embodiment.

FIG. 21 is a schematic diagram depicting an example of a potential of the sensor pixel according to the eleventh embodiment.

FIG. 22 is a schematic diagram depicting an overall configuration example of an electronic device.

FIG. 23 is a view depicting an example of a schematic configuration of an endoscopic surgery system.

FIG. 24 is a block diagram depicting an example of a functional configuration of a camera head and a camera control unit (CCU).

FIG. 25 is a block diagram depicting an example of a schematic configuration of a vehicle control system.

FIG. 26 is an explanatory diagram depicting an example of installation positions of an outside-vehicle information detector and an imaging unit.

### MODE FOR CARRYING OUT THE INVENTION

Hereinafter, embodiments of a solid-state imaging device will be described with reference to the drawings. Although main components of the solid-state imaging device will be mainly described below, the solid-state imaging device may have components and functions that are not depicted or described. The following description does not exclude components and functions that are not depicted or described.

### First Embodiment

### [Configuration of Solid-State Imaging Device 101]

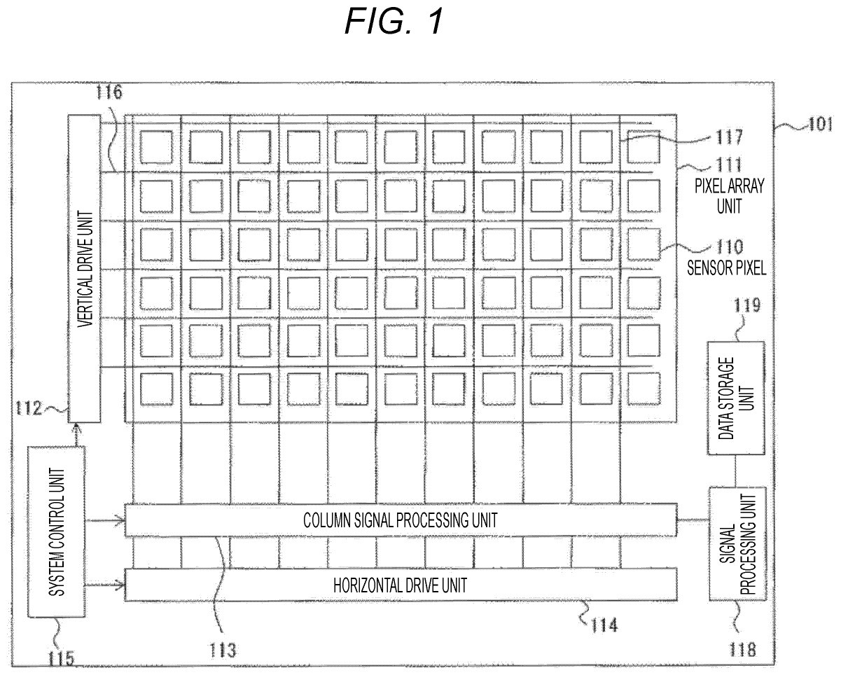

FIG. 1 is a block diagram depicting a functional configuration example of a solid-state imaging device 101 according to a first embodiment.

The solid-state imaging device 101 is a so-called rolling shutter type back-illuminated image sensor such as a complementary metal oxide semiconductor (CMOS) image sensor. The solid-state imaging device 101 receives light from a subject, photoelectrically converts the light, and generates an image signal to capture an image.

The rolling shutter type means control in which each sensor pixel 110 of a pixel array unit 111 in the solid-state imaging device 101 is sequentially exposed and read for each row.

The back-illuminated image sensor refers to an image sensor having a configuration in which a photoelectric converter such as a photodiode that receives light from a subject and converts the light into an electric signal is provided between a light receiving surface on which the light from the subject enters and a wiring layer provided with wiring such as a transistor that drives each pixel.

The solid-state imaging device 101 includes, for example, the pixel array unit 111, a vertical drive unit 112, a column signal processing unit 113, a data storage unit 119, a horizontal drive unit 114, a system control unit 115, and a signal processing unit 118.

In the solid-state imaging device 101, the pixel array unit 111 is formed on a semiconductor substrate 11 (described later). Peripheral circuits such as the vertical drive unit 112, the column signal processing unit 113, the data storage unit 119, the horizontal drive unit 114, the system control unit 115, and the signal processing unit 118 are formed on the same semiconductor substrate 11 as the pixel array unit 111, for example.

The pixel array unit 111 includes a plurality of the sensor pixels 110 including a photoelectric converter (described later) that generates and accumulates charges according to the amount of light incident from the subject. As depicted in FIG. 1, the sensor pixels 110 are arranged in a horizontal direction (row direction) and a vertical direction (column direction). In the pixel array unit 111, a pixel drive line 116 is wired along the row direction for each pixel row including the sensor pixels 110 arrayed in a line in the row direction, and a vertical signal line (VSL) 117 is wired along the column direction for each pixel column including the sensor pixels 110 arrayed in a line in the column direction.

The vertical drive unit 112 includes a shift register, an address decoder, and the like. The vertical drive unit 112 supplies a signal and the like to each of the plurality of sensor pixels 110 through the plurality of pixel drive lines 116, thereby driving all of the plurality of sensor pixels 110 in the pixel array unit 111 at the same time or in units of pixel rows.

The vertical drive unit 112 includes, for example, two scanning systems of a read scanning system and a sweep scanning system. The read scanning system sequentially selects and scans the unit pixels of the pixel array unit 111 row by row in order to read a signal from the unit pixel. The sweep scanning system performs sweep scanning on a read row on which read scanning is performed by the read scanning system prior to the read scanning by a time corresponding to a shutter speed.

The sweep scanning by the sweep scanning system is performed so that unnecessary charges are swept out from the photoelectric converter 51 (described later) of the unit pixel of the read row. This is referred to as reset. Then, a so-called electronic shutter operation is performed by sweeping unnecessary charges by the sweep scanning system, that is, resetting. Here, the electronic shutter operation refers to an operation of discarding the photoelectric charges of the photoelectric converter 51 and newly starting exposure, that is, newly starting accumulation of the photoelectric charges.

The signal read by read operation by the read scanning system corresponds to the amount of light incident after the last read operation or the electronic shutter operation. A period from a read timing by the last read operation or a sweep timing by the electronic shutter operation to a read timing by the present read operation is a photocharge accumulation time in the unit pixel, that is, an exposure time.

A signal output from each unit pixel of the pixel row selectively scanned by the vertical drive unit 112 is supplied to the column signal processing unit 113 through each of the vertical signal lines 117. The column signal processing unit 113 performs predetermined signal processing on the signal output from each unit pixel of the selected row through the VSL 117 for each pixel column of the pixel array unit 111, and temporarily holds the pixel signal after the signal processing.

Specifically, the column signal processing unit 113 includes, for example, a shift register, an address decoder, and the like, performs noise removal processing, correlated double sampling processing, analog/digital (A/D) conversion A/D conversion processing of an analog pixel signal, and the like, and generates a digital pixel signal. The column signal processing unit 113 supplies the generated pixel signal to the signal processing unit 118.

The horizontal drive unit 114 includes a shift register, an address decoder, and the like, and sequentially selects a unit circuit corresponding to the pixel column of the column signal processing unit 113. The selective scanning is performed by the horizontal drive unit 114 so that the pixel signals subjected to the signal processing for each unit circuit in the column signal processing unit 113 are sequentially output to the signal processing unit 118.

The system control unit 115 includes a timing generator and the like that generate various timing signals. The system control unit 115 performs drive control of the vertical drive unit 112, the column signal processing unit 113, and the horizontal drive unit 114 on the basis of the timing signal generated by the timing generator.

The signal processing unit 118 performs signal processing such as arithmetic processing on the pixel signal supplied from the column signal processing unit 113 while temporarily storing data in the data storage unit 119 as necessary, and outputs an image signal including each pixel signal.

The data storage unit 119 temporarily stores data necessary for signal processing in the signal processing unit 118.

### [Configuration of Sensor Pixel 110]

### (Circuit Configuration Example)

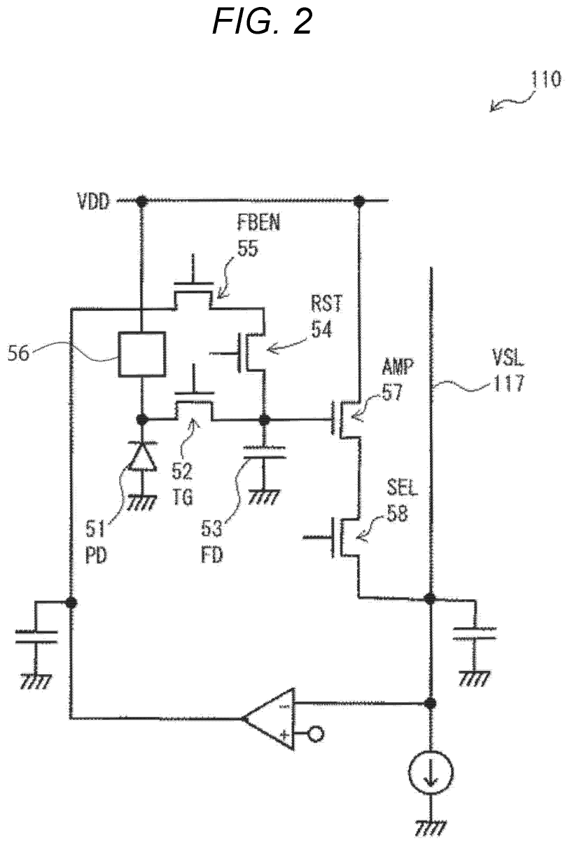

Next, a circuit configuration example of the sensor pixel 110 provided in the pixel array unit 111 of FIG. 1 will be described with reference to FIG. 2. FIG. 2 depicts a circuit configuration example in any one sensor pixel 110 among the plurality of sensor pixels 110 provided in the pixel array unit 111.

In the example depicted in FIG. 2, the sensor pixel 110 implements an FD-type rolling shutter. In the example of FIG. 2, the sensor pixel 110 in the pixel array unit 111 includes, for example, a photoelectric converter (PD) 51, a charge transfer unit (TG) 52, a floating diffusion (FD) 53 as a charge holding unit and a charge-voltage converter, a reset transistor (RST) 54, a feedback enable transistor (FBEN) 55, a discharge path portion 56, an amplification transistor (AMP) 57, a selection transistor (SEL) 58, and the like.

Furthermore, in this example, each of the TG 52, the FD 53, the RST 54, the FBEN 55, the AMP 57, and the SEL 58 is an N-type MOS transistor. A drive signal is supplied to each gate electrode of the TG 52, the FD 53, the RST 54, the FBEN 55, the AMP 57, and the SEL 58. Each drive signal is a pulse signal in which a high-level state becomes an active state, that is, an on state, and a low-level state becomes an inactive state, that is, an off state. Note that, hereinafter, setting the drive signal to the active state is also referred to as turning on the drive signal, and setting the drive signal to the inactive state is also referred to as turning off the drive signal.

The PD 51 is, for example, a photoelectric conversion element including a PN-junction photodiode, and receives light from a subject, generates charges corresponding to the amount of received light by photoelectric conversion, and accumulates the charges.

The TG 52 is connected between the PD 51 and the FD 53, and transfers the charges accumulated in the PD 51 to the FD 52 according to a drive signal applied to the gate electrode of the TG 53.

The FD 53 is a region that temporarily holds the charges accumulated in the PD 51. Furthermore, the FD 53 is also a floating diffusion region that converts the charges transferred from the PD 51 through the TG 52 into an electric signal (for example, voltage signal) and outputs the electric signal. The FD 53 is connected with the RST 54 and also connected with the VSL 117 through the AMP 57 and the SEL 58.

The RST 54 includes a drain connected to the FBEN 55 and a source connected to the FD 53. The RST 54 initializes, that is, resets the FD 53 according to a drive signal applied to the gate electrode.

The FBEN 55 controls a reset voltage to be applied to the RST 54.

The discharge path portion 56 is connected between a power supply (reference voltage node) VDD and the PD 51. A cathode of the PD 51 is commonly connected to one end of the discharge path portion 56 and a source of the TG 52.

The AMP 57 includes a gate electrode connected to the FD 53 and a drain connected to the power supply VDD, and serves as an input unit of a source follower circuit that reads electric charges obtained by photoelectric conversion in the PD 51. That is, the AMP 57 has a source connected to the VSL 117 through the SEL 58, thereby configuring a source follower circuit together with a constant current source connected to one end of the VSL 117.

The SEL 58 is connected between the source of the AMP 57 and the VSL 117, and a selection signal is supplied to the gate electrode of the SEL 58. When the selection signal is turned on, the SEL 58 is in a conductive state, and the sensor pixel 110 in which the SEL 58 is provided is in a selected state. When the sensor pixel 110 is in the selected state, the pixel signal output from the AMP 57 is read out by the column signal processing unit 113 through the VSL 117.

Furthermore, in the pixel array unit 111, a plurality of pixel drive lines 116 is wired, for example, for each pixel row. Then, each drive signal is supplied from the vertical drive unit 112 to the selected sensor pixel 110 through the plurality of pixel drive lines 116.

Note that the pixel circuit depicted in FIG. 2 is an example of a pixel circuit that can be used for the pixel array unit 111, and a pixel circuit having another configuration can also be used.

### (Planar Configuration Example and Cross-Sectional Configuration Example)

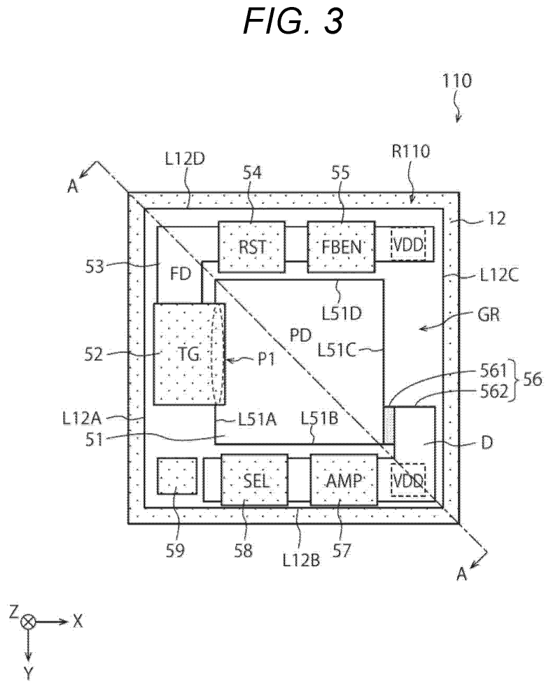

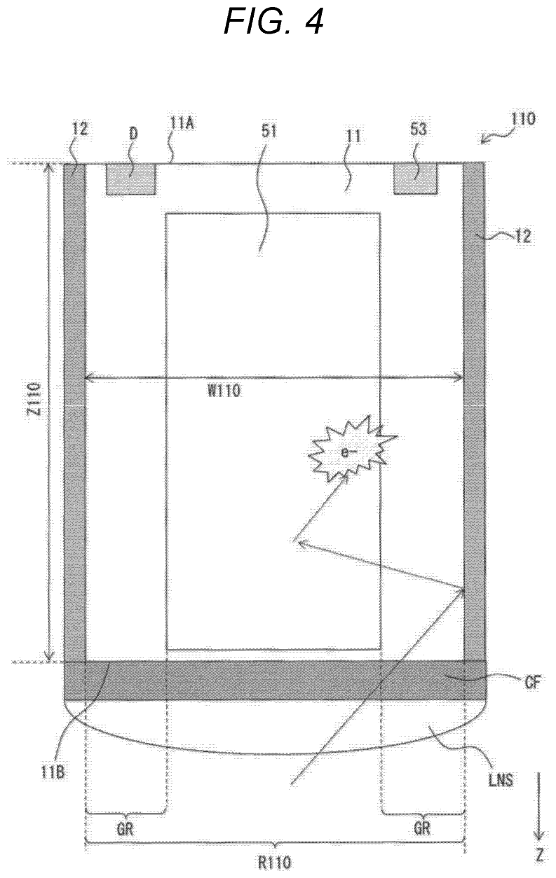

Next, a planar configuration example and a cross-sectional configuration example of the sensor pixels 110 provided in the pixel array unit 111 of FIG. 1 will be described with reference to FIGS. 3 and 4. FIG. 3 depicts a planar configuration example of one sensor pixel 110 among the plurality of sensor pixels 110 configuring the pixel array unit 111. FIG. 4 depicts a cross-sectional configuration example of one sensor pixel 110, and corresponds to a cross section in an arrow direction along a section line A-A depicted in FIG. 3.

As depicted in FIGS. 3 and 4, the pixel array unit 111 includes, for example, a PD 51 embedded in the semiconductor substrate 11 extending in an XY plane, and a pixel separation portion 12 provided in the semiconductor substrate 11 so as to surround the PD 51. The semiconductor substrate 11 includes a semiconductor material such as silicon (Si), and has a front surface 11A extending in the XY plane and a back surface 11B located on a side opposite to the front surface 11A in a Z-axis direction which is a thickness direction orthogonal to the XY plane. On the back surface 11B, for example, a color filter CF and an on-chip lens LNS are sequentially stacked. The pixel separation portion 12 is a physical separation wall that extends from the front surface 11A to the back surface 11B in the thickness direction and separates the semiconductor substrate 11 into the plurality of pixel regions R110 in the XY plane.

Note that, in the present embodiment, the semiconductor substrate 11 is, for example, P-type (first conductivity type), and the PD 51 is N-type (second conductivity type).

The sensor pixels 110 are formed one by one in one pixel region R110 partitioned by the pixel separation portion 12. The adjacent sensor pixels 110 are electrically separated, optically separated, or optically and electrically separated from each other by the pixel separation portion 12. The pixel separation portion 12 may include, for example, a single-layer film or a multi-layer film of an insulator such as silicon oxide (SiO₂), tantalum oxide (Ta₂O₅), hafnium oxide (HfO₂), or aluminum oxide (Al₂O₃). Furthermore, the pixel separation portion 12 may include a stacked body of a single-layer film or a multi-layer film of the insulator such as tantalum oxide, hafnium oxide, and the like aluminum oxide and a silicon oxide film. The pixel separation portion 12 including the insulator described above can optically and electrically separate the sensor pixels 110. The pixel separation portion 12 including such an insulator is also referred to as a front full trench isolation (FFTI). Furthermore, the pixel separation portion 12 may include a gap therein. Even in that case, the pixel separation portion 12 can optically and electrically separate the sensor pixels 110. Furthermore, the pixel separation portion 12 may include a metal having a high light shielding property, for example, tantalum (Ta), aluminum (Al), silver (Ag), gold (Au), or copper (Cu). In this case, the sensor pixels 110 can be optically separated. Moreover, polysilicon (polycrystalline silicon) can also be used as a component material of the pixel separation portion 12.

As depicted in FIG. 3, the pixel region R110 of each sensor pixel 110 includes a gap region GR between the PD 51 and the pixel separation portion 12 in addition to the photoelectric converter (PD) 51. The pixel region R110 has a rectangular, preferably square, outer edge including L12A to L12D in the XY plane. The PD 51 has a substantially rectangular outer edge including straight portions L12A to L12D respectively facing straight portions L51A to L51D in the XY plane.

In the gap region GR, for example, the TG 52, the FD 53, the RST 54, the FBEN 55, the discharge path portion 56, the AMP 57, the SEL 58, and the like are provided.

The TG 52 is provided in a portion sandwiched between the straight portion L51A and straight portion L12A in the gap region GR. However, a part of the TG 52 is connected to the PD 51 at a first connection point P1. Furthermore, the RST 54 and the FBEN 55 are provided, for example, in a portion sandwiched between the straight portion L51D and the straight portion L12D in the gap region GR. Moreover, the FD 53 is provided from a portion sandwiched between the straight portion L51A and the straight portion L12A to a portion sandwiched between the straight portion L51D and the straight portion L12D in the gap region GR.

The discharge path portion 56 is provided in a portion sandwiched between the straight portion L51C and the straight portion L12C in the gap region GR. Furthermore, the AMP 57 and the SEL 58 are provided in a portion sandwiched between the straight portion L51B and the straight portion L12B in the gap region GR. Note that the drain D of the AMP 57 is shared with a part of the discharge path portion 56 on the side opposite to the PD 51. Moreover, the drain D is provided from a portion sandwiched between the straight portion L51B and the straight portion L12B to a portion sandwiched between the straight portion L51C and the straight portion L12C in the gap region GR.

As depicted in FIG. 4, the FD 53 is provided between the front surface 11A and the PD 51 in the thickness direction (Z-axis direction).

Furthermore, the solid-state imaging device 101 receives visible light from a subject and performs imaging, for example. However, the solid-state imaging device 101 is not limited thereto, and may receive infrared light and perform imaging, for example. In that case, the sensor pixel 110 has a ratio of a thickness Z110 to a width W110 along the XY plane, that is, an aspect ratio of 3 or more, for example. More specifically, for example, when the width W110 is 2.2 μm, the thickness Z110 is 8.0 μm. Since the aspect ratio is relatively high as described above, for example, optical separation and electrical separation between the sensor pixels 110 are more favorably performed.

Moreover, in the sensor pixel 110, one or more well contacts 59 including copper or the like are connected to the gap region GR other than the region where the PD 51 is formed in the pixel region R110. In the pixel array unit 111, the semiconductor substrate 11 in each pixel region R110 is partitioned and electrically isolated for each sensor pixel 110 by the pixel separation portion 12. Therefore, the potential of the semiconductor substrate 11 in each pixel region R110 is stabilized by connecting the well contact 59.

### (Details of Discharge Path Portion 56)

As depicted in FIG. 3, the discharge path portion 56 is disposed so as to be in contact with the PD 51. Furthermore, in the example shown in FIG. 3, the discharge path portion 56 is disposed so as to be in contact with the end portion of the straight portion L51C.

The discharge path portion 56 is disposed between the PD 51 and a discharge destination of the charge. The discharge destination of the charges is, for example, the reference voltage node VDD electrically connected to the drain D. Charges overflowing from the PD 51 pass through the discharge path portion 56. The discharge path portion 56 functions as a blooming path. Therefore, for example, charges excessively generated in the PD 51 due to incidence of strong light and the like pass through the discharge path portion 56 and are discharged to the reference voltage node VDD. This makes it possible to suppress excessive charges from flowing into the FD unit 53, and suppress blooming (self-pixel blooming). As a result, noise components superimposed on signal charges due to blooming can be suppressed.

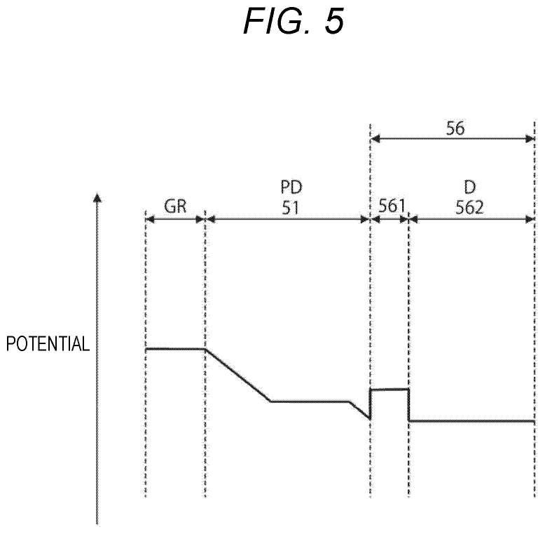

FIG. 5 is a schematic diagram depicting an example of the potential of the sensor pixel 110 according to the first embodiment.

The discharge path portion 56 has a potential different from the potential of the outer peripheral region (gap region GR) surrounding the PD 51 and the discharge path portion 56. More specifically, the potential (potential) of the discharge path portion 56 is lower than the potential of the outer peripheral region (gap region GR).

The discharge path portion 56 includes a first discharge path portion 561 and a second discharge path portion 562.

The first discharge path portion 561 is disposed so as to be in contact with at least a part of the PD 51. The first discharge path portion 561 has a potential lower than the potential of the outer peripheral region (gap region GR) and higher than the lowest value of the potential in the PD 51.

The second discharge path portion 562 is disposed such that electric charges having passed through the first discharge path portion 561 pass therethrough. The second discharge path portion 562 has a potential lower than the potential of the first discharge path portion 561. In the example shown in FIG. 3, the second discharge path portion 562 is shared with the drain D of the AMP 57.

As depicted in FIG. 5, the gap region GR has a potential higher than that of the PD 51. Therefore, the charges remain in the PD 51 without exiting from the gap region GR. Furthermore, the PD 51 has a potential that gradually changes depending on a position. Therefore, the position of the charges accumulated in the PD 51 is adjusted. The charges are accumulated at a position where the potential of the PD 51 is the lowest.

Due to the potential depicted in FIG. 5, excessive electrons generated by the PD 51 by strong light and the like pass over the first discharge path portion 561, pass through the second discharge path portion 562, and are discharged to the reference voltage node VDD.

The potential is adjusted by, for example, an impurity concentration. That is, the discharge path portion 56 has an impurity concentration different from the impurity concentration of the outer peripheral region (gap region GR) surrounding the PD 51 and the discharge path portion 56. The impurity concentration of P-type impurity of the discharge path portion 56 is lower than the P-type impurity concentration of the gap region GR. That is, with adjustment of the density of the impurity concentration, a partial region having a relatively low potential is formed so that excessive charges can pass therethrough. Impurities are introduced into the semiconductor substrate 11 by ion implantation, for example. In this case, the impurity concentration is adjusted by adjusting ion implantation conditions.

The gap region GR is a region in which the P-type impurity is relatively thick. The first discharge path portion 561 is a region in which a P-type impurity is relatively thin. The second discharge path portion 562 is a region where the concentration of the N-type impurity is relatively high.

As described above, according to the first embodiment, the discharge path portion 56 is placed between the PD 51 and the discharge destination (reference voltage node VDD) of the charge, and enables the charges overflowing from the PD 51 to be moved to the reference voltage node VDD. Therefore, blooming can be suppressed.

Note that the placement of the pixel separation portion 12, the well contact 59, the pixel transistor, and the like is not limited to the example depicted in FIG. 3. The pixel transistors include the TG 52, the RST 54, the FBEN 55, the AMP 57, the SEL 58, and the like.

### Comparative Example

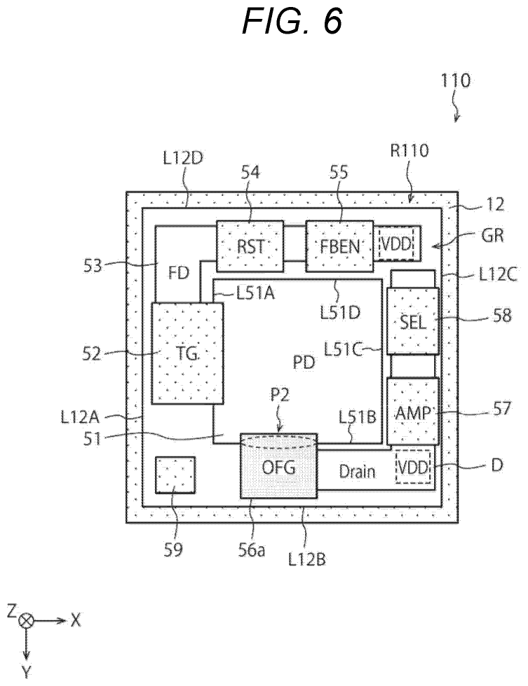

FIG. 6 depicts a planar configuration example of one sensor pixel 110 according to a comparative example. The comparative example is different from the first embodiment in that a discharge transistor (OFG) 56a is provided instead of the discharge path portion 56.

The OFG 56a initializes, that is, resets the PD 51 according to a drive signal applied to the gate electrode. Resetting the PD 51 means to deplete the PD 51.

Note that the OFG 56a is provided in a portion sandwiched between the straight portion L51B and the straight portion L12B in the gap region GR. However, a part of the OFG 56a is connected to the PD 51 at the second connection point P2. Furthermore, the AMP 57 and the SEL 58 are provided in a portion sandwiched between the straight portion L51C and the straight portion L12C in the gap region GR.

The OFG 56a functions as a blooming path, and can reduce blooming (self-pixel blooming). However, in order to arrange the OFG 56a, a predetermined area is required in the pixel region R110. This makes it difficult to miniaturize the sensor pixels 110.

On the other hand, in the first embodiment, the OFG 56a is not provided between the PD 51 and the reference voltage node VDD, and the excessive charges are discharged through the discharge path portion 56. The discharge path portion 56 is formed by ion implantation, and has a required area smaller than that of the OFG 56a. This makes it possible to further miniaturize the sensor pixel 110 while suppressing blooming.

### Second Embodiment

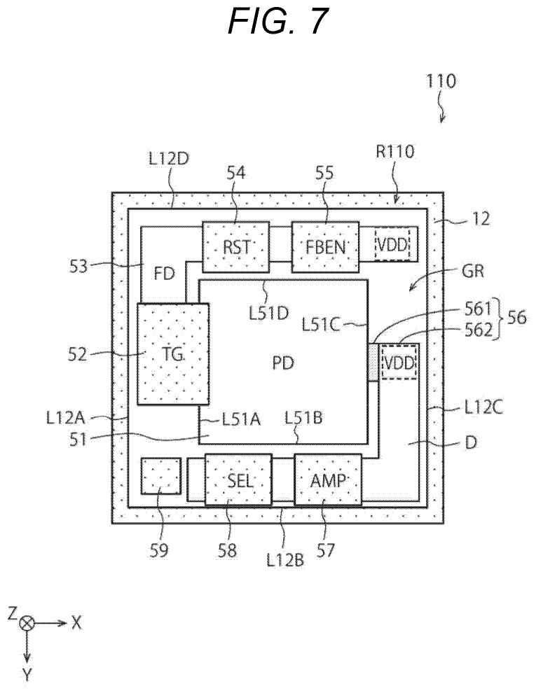

FIG. 7 depicts a planar configuration example of one sensor pixel 110 according to a second embodiment. The second embodiment is different from the first embodiment in the placement of a discharge path portion 56 with respect to a PD 51.

The discharge path portion 56 (first discharge path portion 561) is disposed so as to be in contact with the central portion of a straight portion L51C. The discharge path portion 56 (first discharge path portion 561) only needs to be in contact with at least the PD 51, and the position thereof may be changed.

Furthermore, a discharge destination (reference voltage node VDD) of charges depicted in FIG. 7 is placed to be closer to the PD 51 as compared with the first embodiment described with reference to FIG. 3. This makes possible to suppress the excessive charges from stopping in the middle of the discharge path portion 56 and to more easily discharge the excessive charges.

As in the second embodiment, the placement of the discharge path portion 56 may be changed. In this case, effects similar to those of the first embodiment can be obtained.

### Third Embodiment

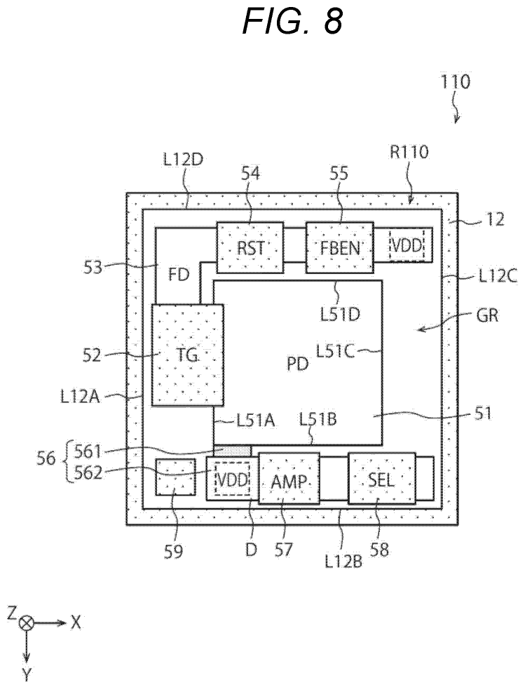

FIG. 8 depicts a planar configuration example of one sensor pixel 110 according to a third embodiment. The third embodiment is different from the first embodiment in the placement of a discharge path portion 56 with respect to a PD 51.

The discharge path portion 56 is disposed so as to be close to a TG 52. The discharge path portion 56 is disposed so as to be in contact with an end portion of the straight portion L51B on a side close to the TG 52.

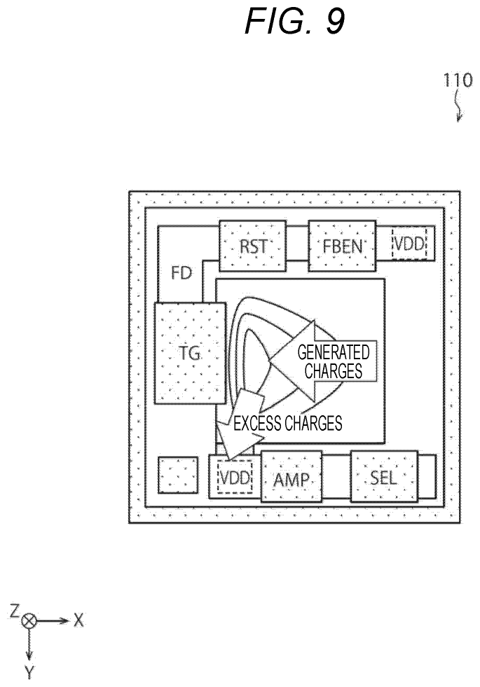

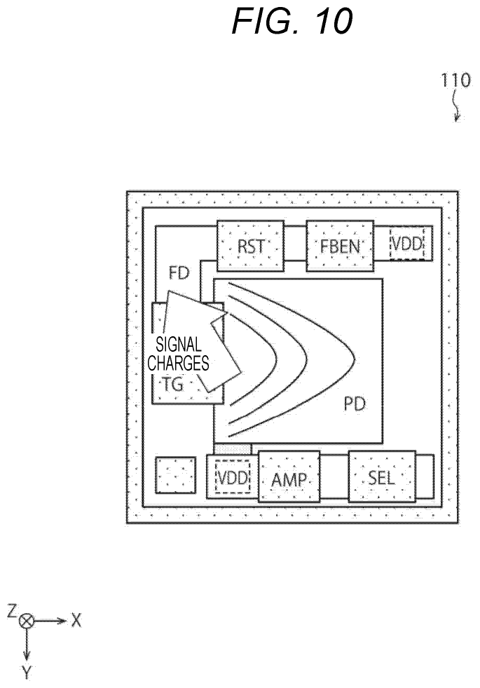

FIGS. 9 and 10 are schematic diagrams depicting an example of a potential of the PD 51 according to the third embodiment. In FIGS. 9 and 10, a potential gradient is indicated by contour lines. FIG. 9 depicts a potential in a case where the TG 52 is in an on state. FIG. 10 depicts a potential in a case where the TG 52 is in an off state.

Normally, in order to facilitate transfer of signal charges from the PD 51 to the FD 53, the potential in the PD 51 is designed to gradually decrease toward the TG 52. Furthermore, the potential in the PD 51 is designed to be the lowest near the TG 52. This is to facilitate transfer of the signal charges accumulated in the PD 51 to the FD 53 through the TG 52.

As depicted in FIG. 9, in a case where the TG 52 is in an off state, the charges generated by the PD 51 are accumulated in a region having the lowest potential near the TG 52. When strong light and the like is incident, charges are excessively generated. Excessive charges are also likely to gather in a region with the lowest potential. As depicted in FIG. 9, since the discharge path portion 56 is disposed so as to be close to the TG 52, excessive charges can be easily discharged to the reference voltage node VDD through the discharge path portion 56.

As depicted in FIG. 10, when the TG 52 is turned on, the potential of the PD 51 immediately below the TG 52 changes. Therefore, the signal charges accumulated in the PD 51 pass through the TG 52 and are transferred to the FD 53. Since the excessive charges are discharged as depicted in FIG. 9, blooming can be suppressed. Consequently, noise can be suppressed.

As in the third embodiment, the discharge path portion 56 may be disposed so as to be close to the TG 52. In this case, effects similar to those of the first embodiment can be obtained.

### Fourth Embodiment

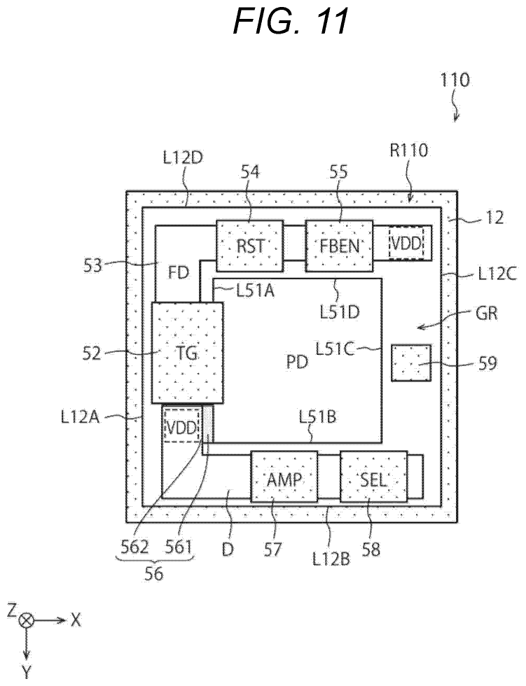

FIG. 11 depicts a planar configuration example of one sensor pixel 110 according to a fourth embodiment. In the fourth embodiment, a PD 51 is disposed closer to a TG 52 than in the third embodiment.

The PD 51 is provided such that an outer edge has a substantially rectangular shape when viewed from a Z direction.

The TG 52 is disposed so as to be in contact with a central portion of a straight portion L51A (first straight portion) of an outer edge of the PD 51 when viewed from a normal direction (Z direction) of a semiconductor substrate 11 on which the PD 51 is provided.

The discharge path portion 56 is disposed so as to be in contact with an end portion of the straight portion L51A (first straight portion) when viewed from the Z direction. Therefore, the discharge path portion 56 can be placed to be closer to the TG 52.

As in the fourth embodiment, the discharge path portion 56 may be disposed so as to be in contact with the straight portion L51A. In this case, effects similar to those of the third embodiment can be obtained.

### Fifth Embodiment

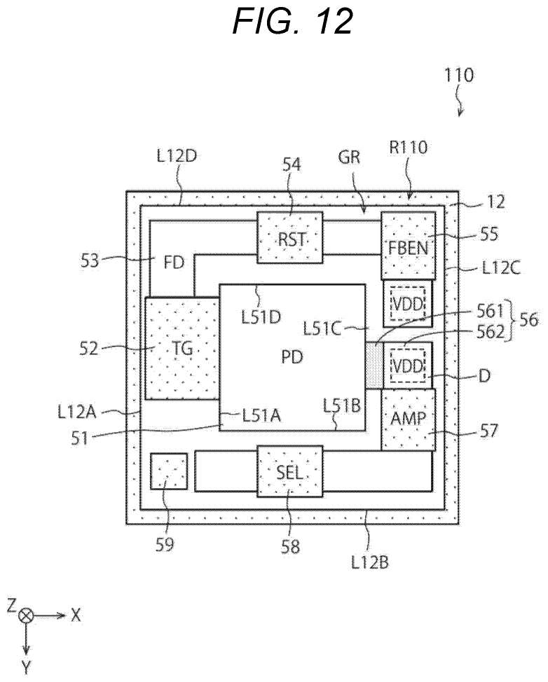

FIG. 12 depicts a planar configuration example of one sensor pixel 110 according to a fifth embodiment. The fifth embodiment is different from the first embodiment in the placement of pixel transistors.

As described in the first embodiment, no OFG 56a is provided in the sensor pixel 110. Therefore, the degree of freedom of placement of other transistors in the sensor pixel 110 can be improved. That is, the degree of freedom of placement of other transistors (RST, SEL, AMP) can be improved by the area of the OFG 56a.

In the example depicted in FIG. 12, an FBEN 55 is disposed near a corner of a gap region GR where a straight portion L12C and a straight portion L12D intersect. The AMP 57 is provided in a portion sandwiched between the straight portion L12C and the straight portion L51C in the gap region GR. The pixel transistors can be placed in all directions of the PD 51, and an area can be effectively utilized.

As in the fifth embodiment, the placement of the pixel transistors may be changed. In this case, effects similar to those of the first embodiment can be obtained.

### Sixth Embodiment

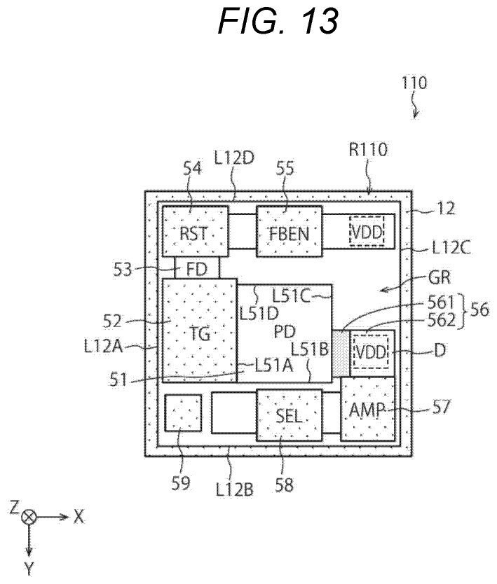

FIG. 13 depicts a planar configuration example of one sensor pixel 110 according to a sixth embodiment. In the sixth embodiment, a size of the sensor pixel 110 is smaller than that in the first embodiment.

As described in the first embodiment, no OFG 56a is provided in the sensor pixel 110. Therefore, even if the size of the sensor pixel 110 is reduced, a pixel transistor can be placed.

Furthermore, in the example depicted in FIG. 13, an RST 54 is provided near a corner where a straight portion L12A and a straight portion L12D intersect in a gap region 54. Therefore, the TG 52 and the RST 54 are placed so as to be close to each other. More specifically, the TG 52 and the RST 54 are placed along a straight portion L12A (second straight portion) of an outer edge of the pixel region R110. Therefore, an area of an FD 53, which is a diffusion region between the TG 52 and the RST 54, can be reduced. As the area of the FD 53 is smaller, parasitic light sensitivity (PLS) can be suppressed. The PLS is, for example, a noise component generated by photoelectric conversion when light directly enters the FD 53.

As in the sixth embodiment, a size of the sensor pixel 110 may be changed. In this case, effects similar to those of the first embodiment can be obtained.

### Seventh Embodiment

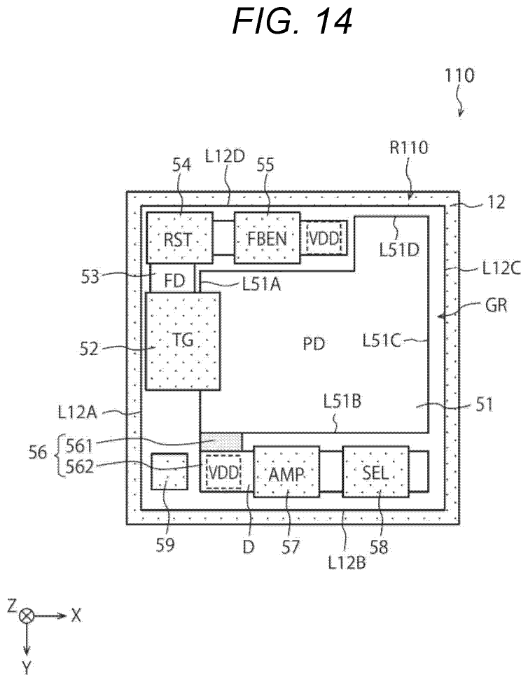

FIG. 14 depicts a planar configuration example of one sensor pixel 110 according to a seventh embodiment. The seventh embodiment is different from the first embodiment in the placement of the pixel transistors and the size of the PD 51.

In the example shown in FIG. 14, a first discharge path portion 561 is disposed so as to be in contact with a straight portion L51B. Therefore, a drain D is disposed not on a straight portion L12C side but on a straight portion L12A side. Furthermore, similarly to the sixth embodiment described with reference to FIG. 13, an RST 54 is provided near a corner where a straight portion L12A and a straight portion L12D intersect in a gap region GR. Therefore, an area of a PD 51 can be increased so that a straight portion L51C approaches a straight portion L12C and a part of the straight portion L51D approaches (protrudes) the straight portion L12D.

Furthermore, similarly to the sixth embodiment described with reference to FIG. 13, an area of an FD 53, which is a diffusion region between the TG 52 and an RST 54, can be reduced, and the PLS can be suppressed.

As in the seventh embodiment, the placement of the pixel transistors and the size of the PD 51 may be changed. In this case, effects similar to those of the first embodiment can be obtained.

### Eighth Embodiment

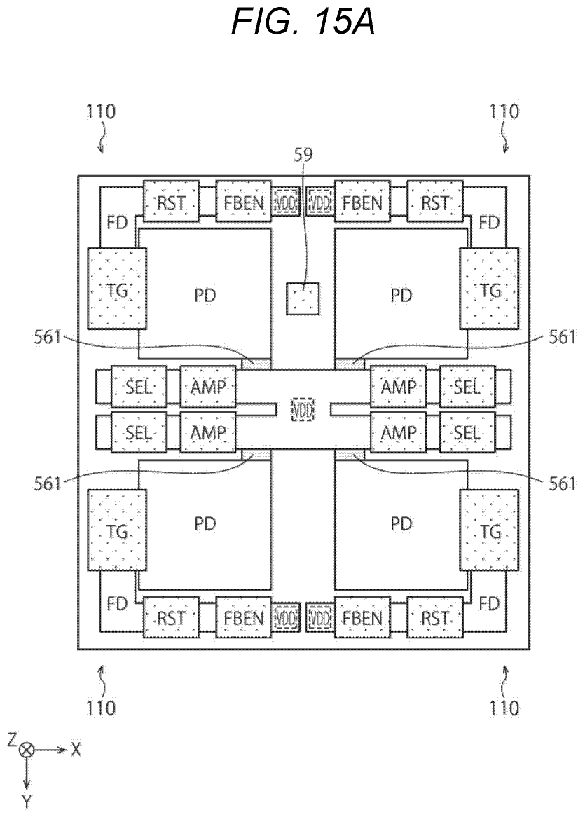

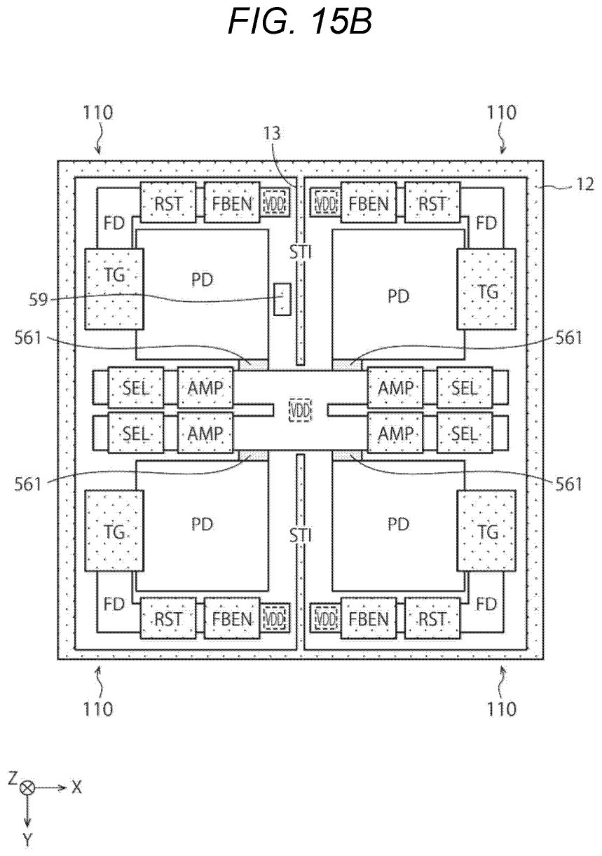

FIG. 15A depicts a planar configuration example of four sensor pixels 110 according to an eighth embodiment. The eighth embodiment is different from the first embodiment in that a reference voltage node VDD, which is a discharge destination of the charge, is shared by four sensor pixels 110.

The reference voltage node VDD is shared by the plurality of sensor pixels 110. In the example shown in FIG. 15A, the reference voltage node VDD is shared by four sensor pixels 110. Therefore, the sensor pixels 110 can be further miniaturized.

Furthermore, as depicted in FIG. 15A, the pixel separation portion 12 may not be provided.

Furthermore, the well contact 59 may also be shared by a plurality of sensor pixels 110.

As in the eighth embodiment, the reference voltage node VDD may be shared by a plurality of sensor pixels 110. In this case, effects similar to those of the first embodiment can be obtained.

### <Modification of Eighth Embodiment>

FIG. 15B depicts a planar configuration example of four sensor pixels 110 according to a modification of the eighth embodiment. The modification of the eighth embodiment is different from the eighth embodiment in that a pixel separation portion 12 is provided.

In the example depicted in FIG. 15B, the pixel separation portion 12 is placed to cover the four sensor pixels 110.

The sensor pixel 110 further includes element isolation portions 13. The element isolation portion 13 is placed to extend from the pixel separation portion 12 to a drain D of an AMP 57. The element isolation portion 13 is used for isolation between the PD 51 and an element around the PD 51 such as a pixel transistor. The element isolation portion 13 is also referred to as shallow trench isolation (STI).

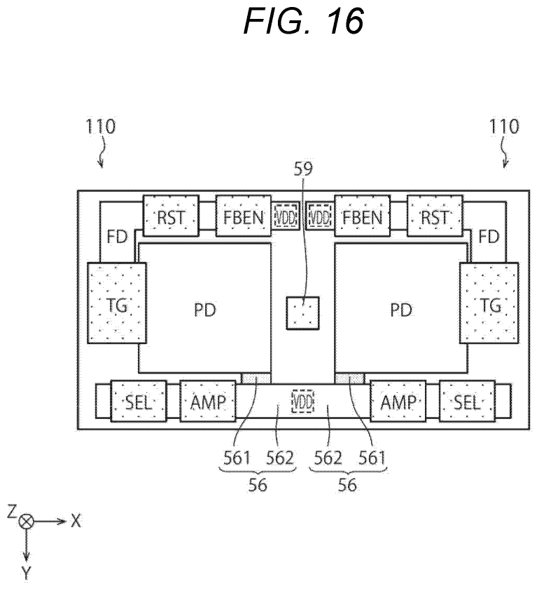

Note that the placement of the pixel separation portion 12 and the element isolation portion 13 is not limited to the example depicted in FIG. 16.

As in a modification of the eighth embodiment, the pixel separation portion 12 may be provided. In this case, effects similar to those of the eighth embodiment can be obtained.

### Ninth Embodiment

FIG. 16 depicts a planar configuration example of two sensor pixels 110 according to a ninth embodiment. The ninth embodiment is different from the eighth embodiment in that the number of sensor pixels 110 sharing the reference voltage node VDD, which is a discharge destination of the charge, is different.

In the example shown in FIG. 16, the reference voltage node VDD is shared by two sensor pixels 110.

As in the ninth embodiment, the number of sensor pixels 110 sharing the reference voltage node VDD may be changed. In this case, effects similar to those of the eighth embodiment can be obtained.

### Tenth Embodiment

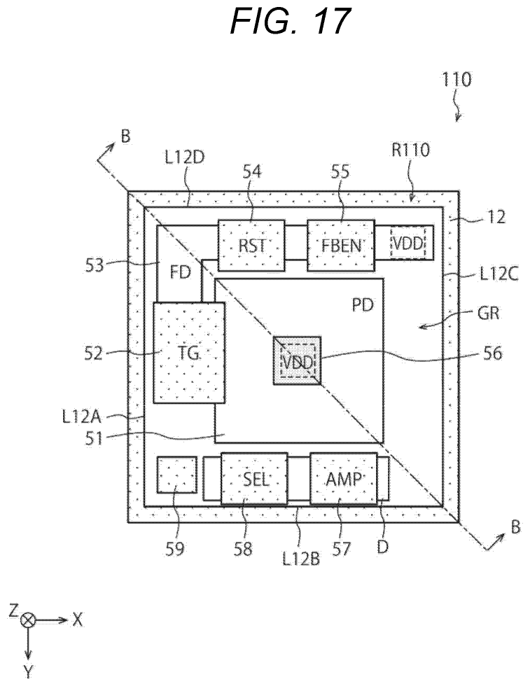

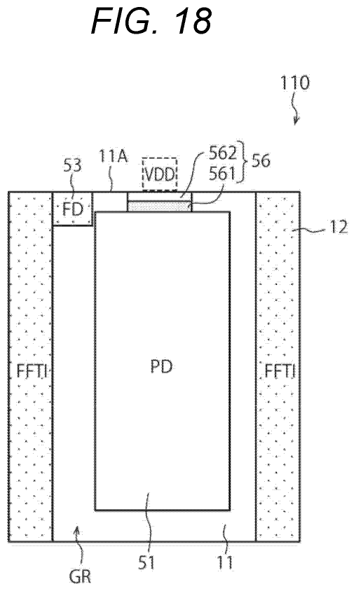

FIG. 17 depicts a planar configuration example of one sensor pixel 110 according to a tenth embodiment. FIG. 18 depicts a cross-sectional configuration example of one sensor pixel 110 according to the tenth embodiment, and corresponds to a cross section in an arrow direction along a section line B-B depicted in FIG. 17. The tenth embodiment is different from the first embodiment in the placement of the discharge path portion 56.

As depicted in FIG. 18, a PD 51 is disposed so as to be embedded in a semiconductor substrate 11.

At least a part of a discharge path portion 56 is disposed so as to extend in a normal direction (Z direction) of a substrate surface of the semiconductor substrate 11. As depicted in FIG. 18, the discharge path portion 56 is disposed between the PD 51 and a front surface 11A.

As depicted in FIG. 17, the discharge path portion 56 is disposed so as to overlap the PD 51 when viewed from the Z direction. More specifically, the discharge path portion 56 is disposed at a center portion of the PD 51 when viewed from the Z direction. Therefore, excessive charges can be discharged in the Z direction. Note that the discharge path portion 56 is not connected to the drain D of the AMP 57.

Note that a contact and the like electrically connected to a fixed power supply of a voltage VDD may be provided at a position of a reference voltage node VDD depicted in FIG. 18 so as to extend in the Z direction.

As in the tenth embodiment, the discharge path portion 56 may be disposed so as to extend along the Z direction. In this case, effects similar to those of the first embodiment can be obtained.

### Eleventh Embodiment

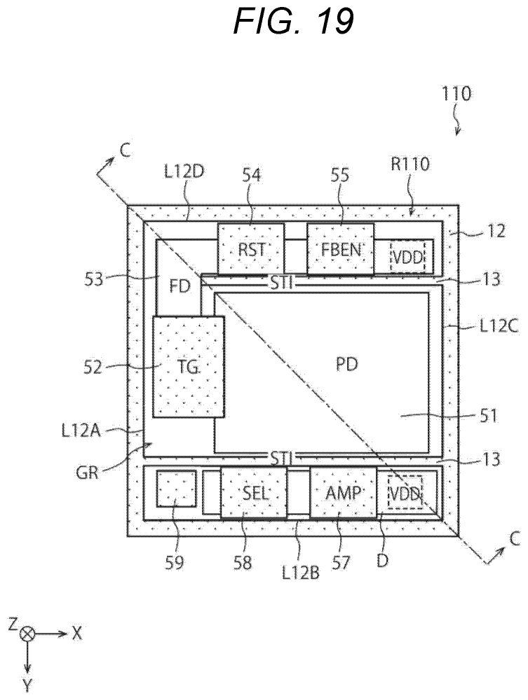

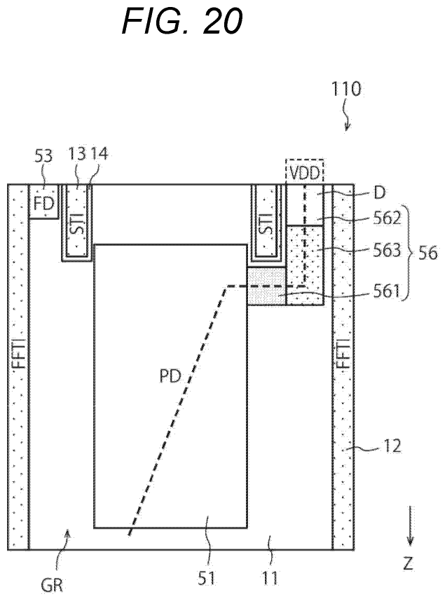

FIG. 19 depicts a planar configuration example of one sensor pixel 110 according to an eleventh embodiment. FIG. 20 depicts a cross-sectional configuration example of one sensor pixel 110 according to the eleventh embodiment, and corresponds to a cross section in an arrow direction along a section line C-C depicted in FIG. 19. The eleventh embodiment is different from the tenth embodiment in a path of the discharge path portion 56.

The sensor pixel 110 further includes element isolation portions 13. The two element isolation portions 13 are placed along each of straight portions L12B and L12D. The element isolation portion 13 is used for isolation between the PD 51 and an element around the PD 51 such as a pixel transistor.

In the example depicted in FIG. 20, a part of the discharge path portion 56 is disposed so as to extend from at least a part of the PD 51 in a direction along a substrate surface (XY plane) of a semiconductor substrate 11. The other part of the discharge path portion 56 is disposed so as to extend in the Z direction from a part of the discharge path portion 56.

The discharge path portion 56 further includes a third discharge path portion 563.

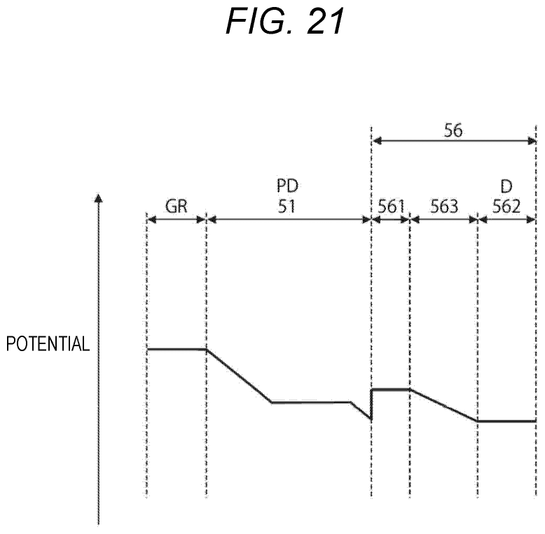

The third discharge path portion 563 is disposed between the first discharge path portion 561 and the second discharge path portion 562. The third discharge path portion 563 has a potential between a potential of the first discharge path portion 561 and a potential of the second discharge path portion 562 (see FIG. 21).

The third discharge path portion 563 is a region in which an N-type impurity is relatively thin. Note that the first discharge path portion 561 is a region in which the P-type impurity is relatively thin. The second discharge path portion 562 is a region where the concentration of the N-type impurity is relatively high.

The N-type third discharge path portion 563 having a low concentration is disposed between the first discharge path portion 561 and the second discharge path portion 562. This makes it possible to suppress generation of dark current by an electric field of the discharge path portion 56. The dark current becomes a noise component superimposed on the signal charges.

In the example depicted in FIG. 20, the first discharge path portion 561 is disposed as a part of the discharge path portion 56 so as to be in contact with a side surface of an outer edge of the PD 51. The second discharge path portion 562 and the third discharge path portion 563 are disposed to extend in the Z direction as other portions of the discharge path portion 56.

Note that the discharge path portion 56 is disposed inside the semiconductor substrate 11 and therefore is not depicted in FIG. 19. Furthermore, the discharge path portion 56 is disposed so as to overlap a part of the element isolation portion 13 when viewed from the Z direction.

Furthermore, the sensor pixel 110 further includes a fixed charge film 14. The fixed charge film 14 is placed around the element isolation portion 13. The fixed charge film 14 is formed using a high dielectric having a negative fixed charge so that a positive charge (hole) accumulation region is formed at an interface portion with the semiconductor substrate 11 to suppress generation of a dark current. The PD 51 and a reference voltage node VDD are preferably disposed close to each other as described in the second embodiment. This makes it possible to more easily discharge the excessive charges. In this case, it is necessary to place the discharge path portion 56 in the vicinity of the element isolation portion 13, and may be affected by dark current. Therefore, with provision of the fixed charge film 14, the dark current generated in the vicinity of the element isolation portion 13 can be suppressed. Therefore, the provision of the fixed charge film 14 makes it possible to easily discharge excessive charges while suppressing noise due to dark current.

FIG. 21 is a schematic diagram depicting an example of a potential of the sensor pixel 110 according to the eleventh embodiment. FIG. 21 depicts a potential corresponding to a position of a broken line depicted in FIG. 20.

As described above, the third discharge path portion 563 has a potential between the potential of the first discharge path portion 561 and the potential of the second discharge path portion 562. The discharge path portion 56 may have a potential that gradually decreases from the PD 51 to the reference voltage node VDD. The third discharge path portion 563 has, for example, a potential that gradually decreases from the first discharge path portion 561 to the second discharge path portion 562. Therefore, the excessive charges can be easily discharged to the reference voltage node VDD.

As in the eleventh embodiment, the discharge path portion 56 may be disposed to extend along the Z direction at a position away from the PD 51 when viewed from the Z direction. In this case, effects similar to those of the tenth embodiment can be obtained.

### <Application Example to Electronic Devices>

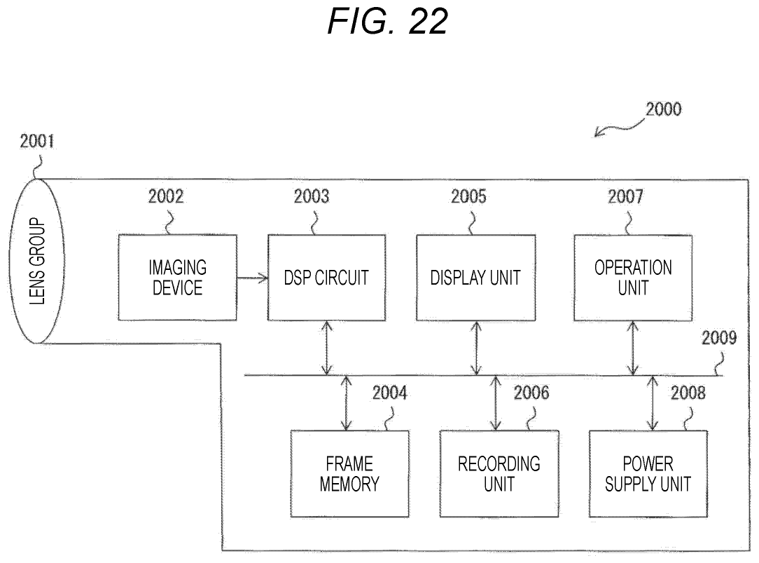

FIG. 22 is a block diagram depicting a configuration example of a camera 2000 as an electronic device to which the present technology is applied.

The camera 2000 includes an optical unit 2001 including a lens group and the like, an imaging device (imaging device) 2002 to which the above-described solid-state imaging device 101 and the like (hereinafter, the solid-state imaging device is referred to as a solid-state imaging device 101 or the like) are applied, and a digital signal processor (DSP) circuit 2003 which is a camera signal processing circuit. Furthermore, the camera 2000 also includes a frame memory 2004, a display unit 2005, a recording unit 2006, an operation unit 2007, and a power supply unit 2008. The DSP circuit 2003, the frame memory 2004, the display unit 2005, the recording unit 2006, the operation unit 2007, and the power supply unit 2008 are connected to one another through a bus line 2009.

The optical unit 2001 captures incident light (image light) from a subject and forms an image on an imaging surface of the imaging device 2002. The imaging device 2002 converts the light amount of the incident light from which an image is formed on the imaging surface by the optical unit 2001 into an electric signal in units of pixels and outputs the electric signal as a pixel signal.

The display unit 2005 includes, for example, a panel type display device such as a liquid crystal panel or an organic EL panel, and displays a moving image or a still image captured by the imaging device 2002. The recording unit 2006 records the moving image or the still image captured by the imaging device 2002 on a recording medium such as a hard disk or a semiconductor memory.

The operation unit 2007 issues operation commands for various functions of the camera 2000 in response to an operation performed by a user. The power supply unit 2008 appropriately supplies various power sources serving as operation power sources of the DSP circuit 2003, the frame memory 2004, the display unit 2005, the recording unit 2006, and the operation unit 2007 to these supply targets.

As described above, the above-described solid-state imaging device 101 and the like are used as the imaging device 2002 so that acquisition of a good image can be expected.

### <Example Application to Endoscopic Surgery System>

The technology according to the present disclosure (the present technology) can be applied to various products. For example, the technology according to the present disclosure may be applied to an endoscopic surgery system.

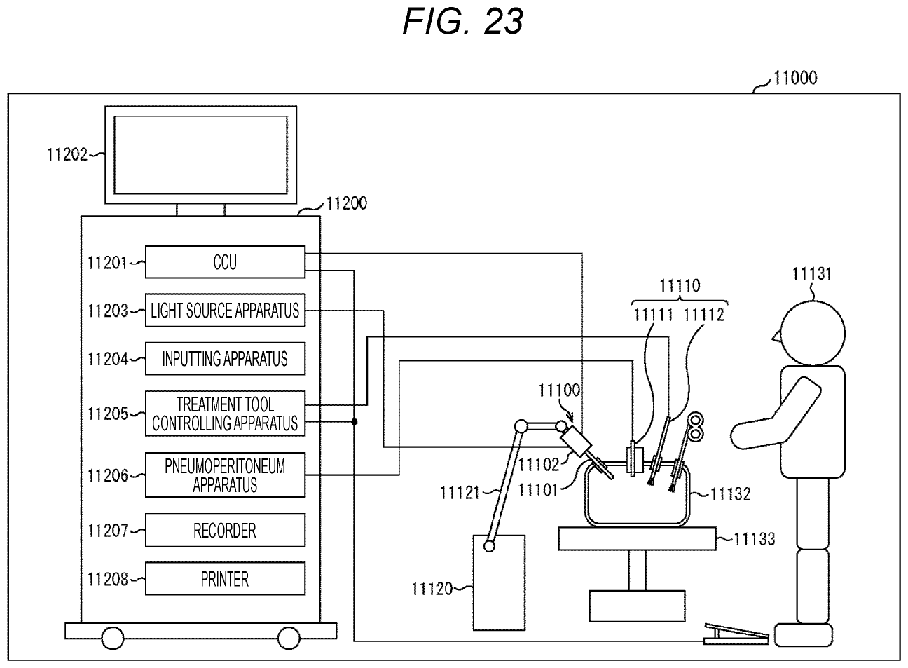

FIG. 23 is a diagram depicting an example of a schematic configuration of an endoscopic surgery system to which the technology according to the present disclosure (the present technology) can be applied.

FIG. 23 depicts a state in which an operator (doctor) 11131 is performing surgery on a patient 11132 on a patient bed 11133 using an endoscopic surgery system 11000. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a camera control unit (CCU) 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

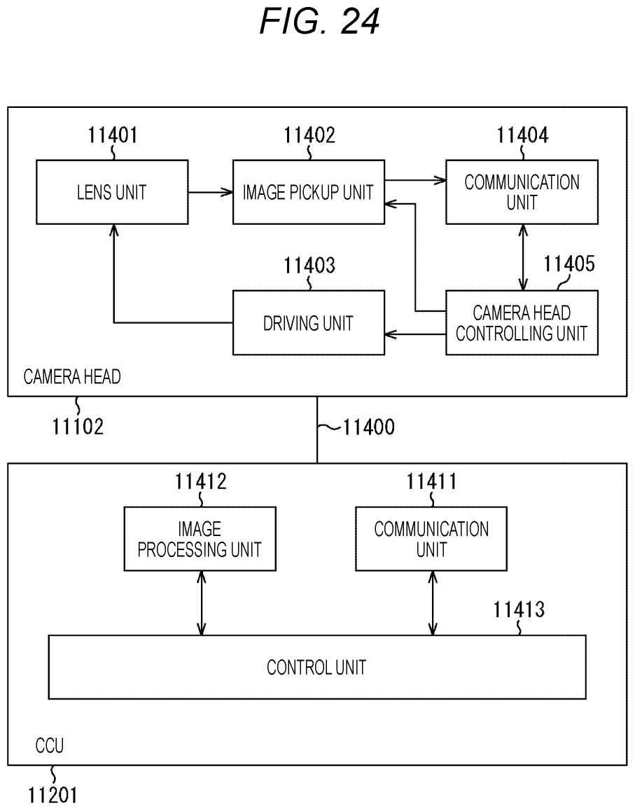

FIG. 24 is a block diagram depicting an example of functional configurations of a camera head 11102 and a CCU 11201 depicted in FIG. 23.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure may be applied to the image pickup unit 11402 of the camera head 11102 among the configurations described above. Specifically, the solid-state imaging device 101 to which each of the above-described embodiments is applied can be applied to the imaging unit 10402. With application of the technology according to the present disclosure to the imaging unit 10402, deterioration in image quality of a surgical site image obtained by the imaging unit 10402 can be suppressed, an S/N ratio can be improved, and a high dynamic range can be realized. Therefore, a clearer surgical site image can be obtained, and the operator can reliably confirm the surgical site.

Note that, here, the endoscopic surgery system has been described as an example, but the technology according to the present disclosure may be applied to, for example, a microscopic surgical system and the like.

### <Application Example to Mobile Body>

The technology according to the present disclosure (the present technology) can be applied to various products. For example, the technology according to the present disclosure may be achieved in a form of an apparatus to be mounted to a mobile body of any kind such as an automobile, an electric vehicle, a hybrid electric vehicle, a motorcycle, a bicycle, a personal mobility, an airplane, a drone, a vessel, a robot, and the like.

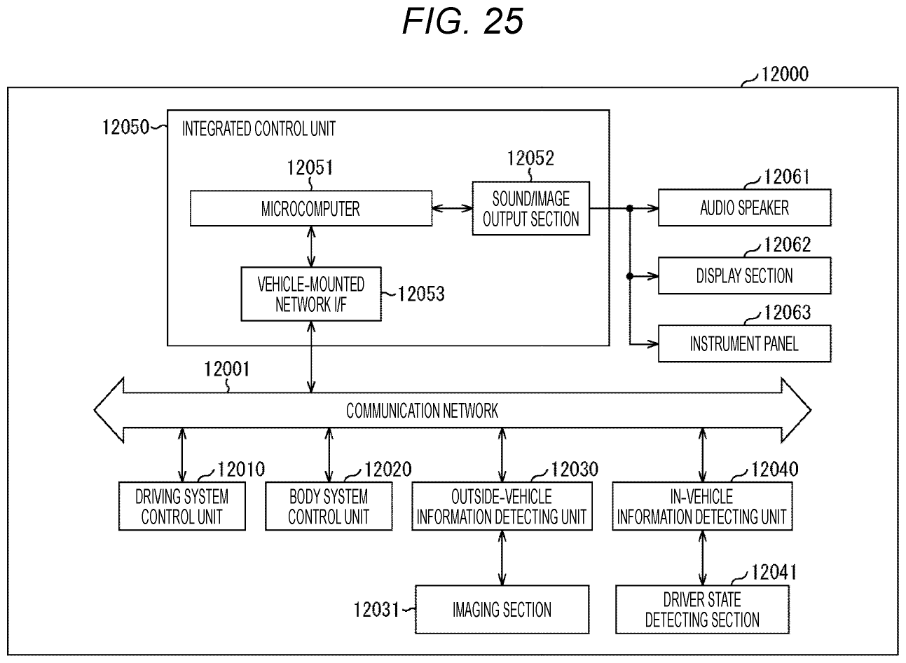

FIG. 25 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are depicted as the output device. The display section 12062 may, for example, include at least one of an on-board display and a head-up display.

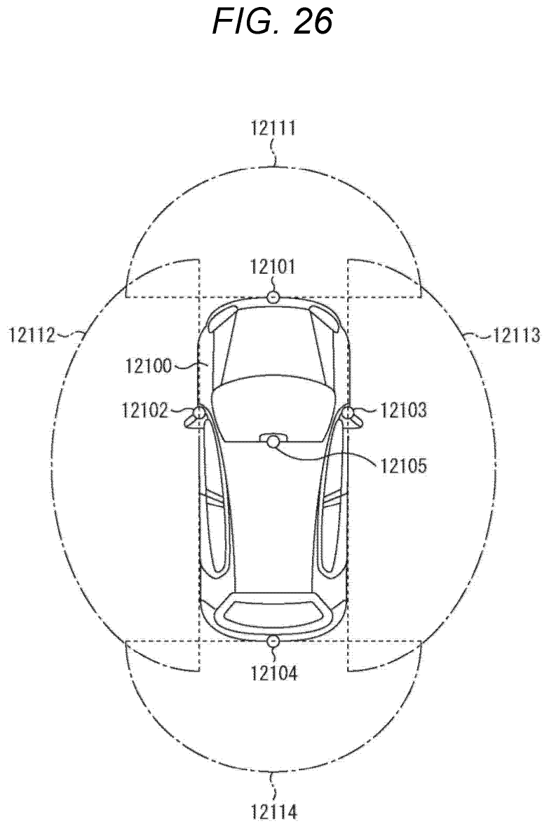

FIG. 26 is a view depicting an example of the installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging sections 12031, 12101, 12102, 12103, 12104, and 12105, the driver state detecting section 12041, and the like among the above-described configurations. Specifically, for example, the solid-state imaging device 101 in FIG. 1 including the imaging device of the present disclosure can be applied to these imaging units and detector. Then, by applying the technology according to the present disclosure, noise can be suppressed, so that safer vehicle traveling can be achieved.

Note that the present technology can have the following configurations.

(1)

A solid-state imaging device including:
a photoelectric converter configured to generate a charge according to an amount of received light; and
a discharge path portion that is disposed between the photoelectric converter and a discharge destination of the charge and through which the charge overflowing from the photoelectric converter passes.
   (2)

The solid-state imaging device according to (1), in which the discharge path portion has a potential different from a potential of an outer peripheral region surrounding the photoelectric converter and the discharge path portion.

(3)

The solid-state imaging device according to (2), in which
the discharge path portion includes:
a first discharge path portion disposed so as to be in contact with at least a part of the photoelectric converter, and having a potential lower than the potential of the outer peripheral region and higher than a lowest value of the potential of the photoelectric converter; and
a second discharge path portion disposed to allow the charge having passed through the first discharge path portion to pass therethrough, and having a potential lower than the potential of the first discharge path portion.
   (4)

The solid-state imaging device according to (3), in which the discharge path portion further includes a third discharge path portion disposed between the first discharge path portion and the second discharge path portion and having a potential between the potential of the first discharge path portion and the potential of the second discharge path portion.

(5)

The solid-state imaging device according to any one of (1) to (4), in which the discharge path portion has a potential that gradually decreases from the photoelectric converter to the discharge destination.

(6)

The solid-state imaging device according to any one of (1) to (5), in which the discharge path portion has an impurity concentration different from an impurity concentration in an outer peripheral region surrounding the photoelectric converter and the discharge path portion.

(7)

The solid-state imaging device according to any one of (1) to (6), in which a discharge transistor that resets the charge of the photoelectric converter is not provided between the photoelectric converter and the discharge destination.

(8)

The solid-state imaging device according to any one of (1) to (7), further including a transfer unit configured to transfer the charge generated by the photoelectric converter, in which
the discharge path portion is disposed so as to be close to the transfer unit.
   (9)

The solid-state imaging device according to any one of (1) to (8), further including a transfer unit configured to transfer the charge generated by the photoelectric converter, in which
the transfer unit is disposed so as to be in contact with a first straight portion of an outer edge of the photoelectric converter when viewed from a normal direction of a substrate surface of a substrate on which the photoelectric converter is provided, and
the discharge path portion is disposed so as to be in contact with the first straight portion when viewed from the normal direction.
   (10)

The solid-state imaging device according to any one of (1) to (9), further including:
a transfer unit configured to transfer the charge generated by the photoelectric converter;
a charge accumulation unit that accumulates the charge transferred by the transfer unit; and
a reset unit configured to reset the charge accumulated in the charge accumulation unit, in which
the transfer unit and the reset unit are placed to be close to each other.
   (11)

The solid-state imaging device according to any one of (1) to (10), further including:
a transfer unit configured to transfer the charge generated by the photoelectric converter;
a charge accumulation unit that stores the charge transferred by the transfer unit; and
a reset unit configured to reset the charge accumulated in the charge accumulation unit, in which
the transfer unit and the reset unit are disposed along a second straight portion of an outer edge of a pixel region.
   (12)

The solid-state imaging device according to any one of (1) to (11), in which
the photoelectric converter is disposed inside a substrate, and
at least a part of the discharge path portion is disposed so as to extend in a normal direction of a substrate surface of the substrate.
   (13)

The solid-state imaging device according to (12), in which the discharge path portion is disposed so as to overlap the photoelectric converter when viewed from the normal direction.

(14)

The solid-state imaging device according to (12), in which
a part of the discharge path portion is disposed so as to extend from at least a part of the photoelectric converter in a direction along the substrate surface of the substrate, and
the other portion of the discharge path portion is disposed so as to extend in the normal direction from a part of the discharge path portion.
   (15)

The solid-state imaging device according to any one of (1) to (14), in which the discharge destination is shared by a plurality of pixels.

(16)

The solid-state imaging device according to any one of (1) to (15), in which the discharge destination is placed to be close to the photoelectric converter.

(17)

The solid-state imaging device according to any one of (1) to (16), in which the discharge destination is a reference voltage node.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

101 Solid-state imaging device
12 Pixel separation portion
51 PD
52 TG
53 FD
54 RST
56 Discharge path portion
561 First discharge path portion
562 Second discharge path portion
563 Third discharge path portion
56a OFG
57 AMP
110 Sensor pixel
D Drain
GR Gap region
L51A Straight portion
L12A Straight portion
R110 Pixel region

1. A solid-state imaging device comprising:
a photoelectric converter configured to generate a charge according to an amount of received light; and
a discharge path portion that is disposed between the photoelectric converter and a discharge destination of the charge and through which the charge overflowing from the photoelectric converter passes.

2. The solid-state imaging device according to claim 1, wherein the discharge path portion has a potential different from a potential of an outer peripheral region surrounding the photoelectric converter and the discharge path portion.

3. The solid-state imaging device according to claim 2, wherein
the discharge path portion includes:
a first discharge path portion disposed to be in contact with at least a part of the photoelectric converter, and having a potential lower than the potential of the outer peripheral region and higher than a lowest value of the potential of the photoelectric converter; and
a second discharge path portion disposed to allow the charge having passed through the first discharge path portion to pass therethrough, and having a potential lower than the potential of the first discharge path portion.

4. The solid-state imaging device according to claim 3, wherein the discharge path portion further includes a third discharge path portion disposed between the first discharge path portion and the second discharge path portion and having a potential between the potential of the first discharge path portion and the potential of the second discharge path portion.

5. The solid-state imaging device according to claim 1, wherein the discharge path portion has a potential that gradually decreases from the photoelectric converter to the discharge destination.

6. The solid-state imaging device according to claim 1, wherein the discharge path portion has an impurity concentration different from an impurity concentration in an outer peripheral region surrounding the photoelectric converter and the discharge path portion.

7. The solid-state imaging device according to claim 1, wherein a discharge transistor that resets the charge of the photoelectric converter is not provided between the photoelectric converter and the discharge destination.

8. The solid-state imaging device according to claim 1, further comprising a transfer unit configured to transfer the charge generated by the photoelectric converter, wherein
the discharge path portion is disposed to be close to the transfer unit.

9. The solid-state imaging device according to claim 1, further comprising a transfer unit configured to transfer the charge generated by the photoelectric converter, wherein
the transfer unit is disposed to be in contact with a first straight portion of an outer edge of the photoelectric converter when viewed from a normal direction of a substrate surface of a substrate on which the photoelectric converter is provided, and
the discharge path portion is disposed to be in contact with the first straight portion when viewed from the normal direction.

10. The solid-state imaging device according to claim 1, further comprising:
a transfer unit configured to transfer the charge generated by the photoelectric converter;
a charge accumulation unit that accumulates the charge transferred by the transfer unit; and
a reset unit configured to reset the charge accumulated in the charge accumulation unit, wherein
the transfer unit and the reset unit are placed to be close to each other.

11. The solid-state imaging device according to claim 1, further comprising:
a transfer unit configured to transfer the charge generated by the photoelectric converter;
a charge accumulation unit that accumulates the charge transferred by the transfer unit; and
a reset unit configured to reset the charge accumulated in the charge accumulation unit, wherein
the transfer unit and the reset unit are disposed along a second straight portion of an outer edge of a pixel region.

12. The solid-state imaging device according to claim 1, wherein
the photoelectric converter is disposed inside a substrate, and
at least a part of the discharge path portion is disposed to extend in a normal direction of a substrate surface of the substrate.

13. The solid-state imaging device according to claim 12, wherein the discharge path portion is disposed to overlap the photoelectric converter when viewed from the normal direction.

14. The solid-state imaging device according to claim 12, wherein
a part of the discharge path portion is disposed to extend from at least a part of the photoelectric converter in a direction along the substrate surface of the substrate, and
the other portion of the discharge path portion is disposed to extend in the normal direction from a part of the discharge path portion.

15. The solid-state imaging device according to claim 1, wherein the discharge destination is shared by a plurality of pixels.

16. The solid-state imaging device according to claim 1, wherein the discharge destination is placed to be close to the photoelectric converter.

17. The solid-state imaging device according to claim 1, wherein the discharge destination is a reference voltage node.
